(19) United States
(12) Patent Application Publication
(10) Pub. No.: US 2025/0142233 A1
(43) Pub. Date: May 1, 2025

(54) STACKED IMAGE SENSOR AND METHOD OF MANUFACTURING THE SAME

(71) Applicant: SAMSUNG ELECTRONICS CO., LTD., Suwon-si (KR)

(72) Inventors: Changhwa Kim, Suwon-si (KR); Gwideok Ryan Lee, Suwon-si (KR); Doowon Kwon, Suwon-si (KR); Daehoon Kim, Suwon-si (KR); Changyong Um, Suwon-si (KR)

(21) Appl. No.: 18/885,926

(22) Filed: Sep. 16, 2024

(30) Foreign Application Priority Data
Oct. 30, 2023 (KR) 10-2023-0147067

(51) Int. Cl. H04N 25/79; H01L 27/146

(52) U.S. Cl. CPC H04N 25/79; H10F 39/018; H10F 39/8037; H10F 39/809; H10F 39/811

(57) ABSTRACT

A stacked image sensor includes a first semiconductor chip, wherein the first semiconductor chip includes a first contact electrically connected to the first transfer transistor and disposed to extend in a Z-axis direction, a second contact electrically connected to the second transfer transistor and disposed to extend in the Z-axis direction, a plurality of third contacts electrically connected with each of the first floating diffusion region and the second floating diffusion region and disposed to extend in the Z-axis direction, and a first metal region configured to electrically connect the plurality of third contacts to one another and disposed to extend in the Z-axis direction, and the first contact, the second contact, and the first metal region contact a first surface of a first interlayer insulation layer where the first contact, the second contact, and the first metal region are formed.

### CROSS-REFERENCE TO RELATED APPLICATION

This application claims priority to Korean Patent Application No. 10-2023-0147067, filed in the Korean Intellectual Property Office on Oct. 30, 2023, the disclosure of which is incorporated by reference herein in its entirety.

### BACKGROUND

Image sensors convert an optical image into an electrical signal and may be used in cameras of portable electronic devices, such as smartphones or tablet computers. Stacked image sensors have been developed for reducing a size of portable electronic devices and enhancing the performance of cameras. In stacked image sensors, image sensors may be one-dimensionally reduced, a resolution of the image sensors may be enhanced, and a signal processing speed of the image sensors may be enhanced.

### SUMMARY

In general, in some aspects, the present disclosure is directed toward an image sensor having enhanced performance.

According to some aspects of the present disclosure, a stacked image sensor includes a first semiconductor chip including a first photoelectric conversion layer, a first floating diffusion region, and a first transfer transistor electrically connecting the first photoelectric conversion layer with the first floating diffusion region, a second photoelectric conversion layer, a second floating diffusion region, and a second transfer transistor electrically connecting the second photoelectric conversion layer with the second floating diffusion region and a second semiconductor chip configured to output a pixel signal based on the first photoelectric conversion layer and the second photoelectric conversion layer, the second semiconductor chip including at least one transistor, wherein the first semiconductor chip includes a first contact electrically connected with the first transfer transistor and disposed to extend in a Z-axis direction, a second contact electrically connected with the second transfer transistor and disposed to extend in the Z-axis direction, a plurality of third contacts electrically connected with each of the first floating diffusion region and the second floating diffusion region and disposed to extend in the Z-axis direction, and a first metal region configured to electrically connect the plurality of third contacts with one another and disposed to extend in the Z-axis direction, and the first contact, the second contact, and the first metal region contact a first surface of a first interlayer insulation layer where the first contact, the second contact, and the first metal region are formed.

According to some aspects of the present disclosure, a stacked image sensor includes a first semiconductor chip including a first photoelectric conversion layer, a first floating diffusion region, and a first transfer transistor electrically connecting the first photoelectric conversion layer with the first floating diffusion region, a second photoelectric conversion layer, a second floating diffusion region, and a second transfer transistor electrically connecting the second photoelectric conversion layer with the second floating diffusion region, a second semiconductor chip configured to output a pixel signal based on the first photoelectric conversion layer and the second photoelectric conversion layer, the second semiconductor chip including at least one transistor, and a third semiconductor chip including a circuit configured to process the pixel signal, wherein the first semiconductor chip includes a first contact electrically connected with the first transfer transistor and disposed to extend in a Z-axis direction, a second contact electrically connected with the second transfer transistor and disposed to extend in the Z-axis direction, a plurality of third contacts electrically connected with each of the first floating diffusion region and the second floating diffusion region and disposed to extend in the Z-axis direction, and a first metal region configured to electrically connect the plurality of third contacts with one another and disposed to extend in the X-axis direction, and the first contact, the second contact, and the first metal region contact a first surface of a first interlayer insulation layer where the first contact, the second contact, and the first metal region are formed.

According to some aspects of the present disclosure, a stacked image sensor includes a pixel array where a plurality of pixels are arranged, a row driver configured to provide a control signal to the pixel array, and a readout circuit configured to read out a pixel signal output from pixels of a row line selected by the row driver, wherein each of the plurality of pixels includes a first photodiode, a first transfer transistor connected with the first photodiode, a second photodiode, a second transfer transistor connected with the second photodiode, a plurality of floating diffusion regions configured to accumulate electric charges generated in the first photodiode and the second photodiode, and a source follower transistor including a gate connected with the plurality of floating diffusion regions, and heights of a first contact and a second contact, which are respectively and electrically connected with the first transfer transistor and the second transfer transistor and extend in a Z-axis direction, are equal to a height of a first metal region which electrically connects, with one another, a plurality of third contacts electrically connected to each of the plurality of floating diffusion regions and extending in the Z-axis direction, wherein the first metal region extends in an X-axis direction.

In some aspects of the present disclosure, a method of manufacturing a stacked image sensor includes forming a transfer transistor and a plurality of floating diffusion regions on a first substrate, forming a first interlayer insulation layer on the first substrate, etching a contact region and a first metal region of the first interlayer insulation layer to form a first recess region, a second recess region, and a third recess region, depositing a first material on the first recess region, the second recess region, and the third recess region, performing a first chemical mechanical polishing (CMP) process, forming a second interlayer insulation layer, etching the second interlayer insulation layer to form a fourth recess region, depositing a second material on the fourth recess region, and performing a second CMP process.

### BRIEF DESCRIPTION OF THE DRAWINGS

Example implementations will be more clearly understood from the following detailed description, taken in conjunction with the accompanying drawings.

FIG. 1 is a block diagram of an examples of an image sensor according to some implementations.

FIG. 2 is a block diagram of examples of a first pixel array, a second pixel array, a logic circuit, and an analog-to-digital converter (ADC) of FIG. 1 according to some implementations.

FIG. 3 is a circuit diagram of an example of a unit pixel of the first pixel array and the second pixel array of FIG. 1 according to some implementations.

FIG. 4 is a perspective view of the first pixel array, the logic circuit, and the ADC of the image sensor of FIG. 1 according to some implementations.

FIG. 5A is a cross-sectional view of an example of a first pixel array of an image sensor according to some implementations.

FIG. 5B is a diagram of an example of a relationship between contacts included in the first pixel array of FIG. 5A according to some implementations.

FIG. 6 is a cross-sectional view of an example of a first pixel array of an image sensor according to some implementations.

FIG. 7 is a diagram of an example of a connection relationship between elements included in a first pixel array and a second pixel array of an image sensor according to some implementations.

FIGS. 8A to 8H are cross-sectional views of an example of a method of manufacturing an image sensor according to some implementations.

FIG. 9 is a flowchart of an example of a method of manufacturing an image sensor according to some implementations.

FIG. 10 is a diagram of an example of a pixel circuit of an image sensor according to some implementations.

### DETAILED DESCRIPTION

Hereinafter, example implementations will be described in detail with reference to the accompanying drawings.

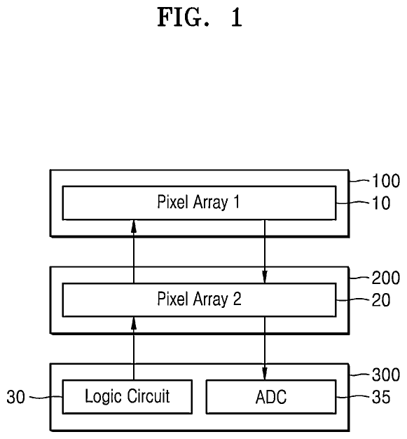

FIG. 1 is a block diagram of an example of an image sensor according to some implementations. In FIG. 1, the image sensor may include a first semiconductor chip 100, a second semiconductor chip 200, and a third semiconductor chip 300. The first semiconductor chip 100, the second semiconductor chip 200, and the third semiconductor chip 300 may be arranged to overlap one another with respect to a plane. The first semiconductor chip 100, the second semiconductor chip 200, and the third semiconductor chip 300 may be sequentially stacked in a vertical direction. The first semiconductor chip 100 may be referred to as an upper substrate, the second semiconductor chip 200 may be referred to as a middle substrate, and the third semiconductor chip 300 may be referred to as a lower substrate.

The first semiconductor chip 100 may include a first pixel array 10. The second semiconductor chip 200 may include a second pixel array 20. The third semiconductor chip 300 may include a logic circuit 30 and an analog-to-digital converter (ADC) 35. The first pixel array 10 may generate an electric charge in proportion to an amount of light incident on the first pixel array 10. The second pixel array 20 may convert a light signal into an electrical signal (i.e., an analog signal) based on control by the logic circuit 30. The second pixel array 20 may output the analog signal to the ADC 35. The ADC 35 may convert the analog signal into a digital signal. The ADC 35 may provide data, based on the digital signal.

In FIG. 1, an image sensor according to some implementations may further include a memory cell array. The memory cell array may store data based on the digital signal. The data may be image data generated by frame units. The number of bits of the data may be determined based on a resolution of the ADC 35. The number of bits of the data may be determined based on a high dynamic range (HDR) supported by the image sensor. Also, the bits of the data may further include at least one extension bit representing information of the data and a position at which the data is generated.

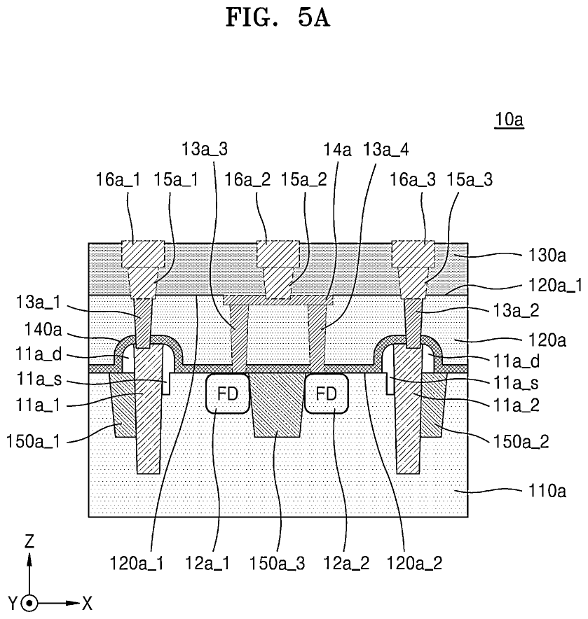

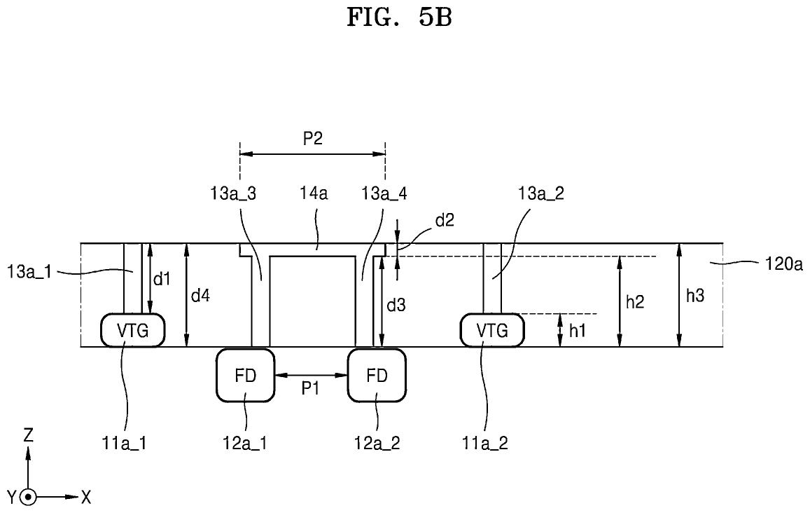

In some implementations, the image sensor may be a 3-stack image sensor that includes the first pixel array 10 and the second pixel array 20, in which the first pixel array 10 and the second pixel array 20 are formed in different chips and stacked. In some implementations, as described below with respect to FIG. 5A, the image sensor may secure a conversion gain, based on a connection structure of a contact region of the first pixel array 10 included in the first semiconductor chip 100.

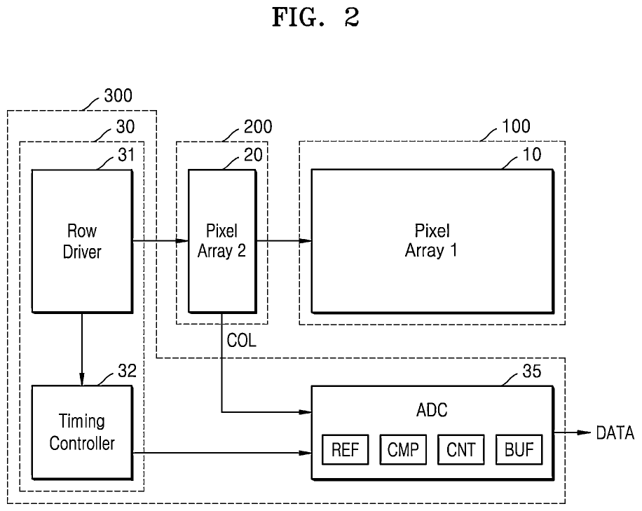

FIG. 2 is a block diagram of examples of the first pixel array 10, the second pixel array 20, the logic circuit 30, and the ADC 35 of FIG. 1 according to some implementations. In FIG. 2, the first pixel array 10 may be implemented in the first semiconductor chip 100. The second pixel array 20 may be implemented in the second semiconductor chip 200. The logic circuit (30 of FIG. 1) may be implemented in the third semiconductor chip 300.

The first pixel array 10 may convert incident light to generate an electrical signal. The second pixel array 20 may include unit pixels that are arranged in a matrix form in a row direction and a column direction. The second pixel array 20 may be driven based on control by the logic circuit 30. In some implementations, the logic circuit 30 may control a plurality of transistors included in the second pixel array 20. The plurality of transistors included in the second pixel array 20 may control an electrical signal transferred from the first pixel array 10.

The logic circuit 30 may efficiently receive data from the second pixel array 20 and may generate an image frame. For example, the logic circuit 30 may use a global shutter scheme where all of unit pixels are simultaneously sensed, a flutter shutter scheme that adjusts the exposure time where all of unit pixels are simultaneously sensed, or a rolling shutter scheme which controls unit pixels by row units, or a coded rolling shutter scheme. The logic circuit 30 may include a row driver 31 and a timing controller 32, and the logic circuit 30 may be connected with the ADC 35.

The row driver 31 may control the second pixel array 20 by row units, based on control by the timing controller 32. The row driver 31 may select at least one row among from rows of the second pixel array 20, based on a row address. The row driver 31 may decode the row address and may be connected with a selection transistor SEL, a reset transistor RG, and a source follower transistor SF each included in the second pixel array 20. The second pixel array 20 may be driven by a plurality of driving signals such as a pixel selection signal, a reset signal, and a charge transfer signal each received from the row driver 31.

The ADC 35 may be connected with the second pixel array 20 through column lines COL. The ADC 35 may convert analog signals, received through the column lines COL from the second pixel array 20, into digital signals. The number of ADCs 35 may be determined based on the number of column lines COL and the number of unit pixels arranged along one row. The ADC 35 may be provided as one or more.

In some implementations, the ADC 35 may include a reference signal generator REF, a comparator CMP, a counter CNT, and a buffer BUF. The reference signal generator REF may generate a ramp signal having a certain slope and may be provided as a reference signal of the comparator CMP. The comparator CMP may compare the analog signal with the ramp signal of the reference signal generator REF and may output comparison signals respectively having shift times based on a valid signal component. The counter CNT may perform a counting operation to generate a counting signal and may provide the counting signal to the buffer BUF. The buffer BUF may include latch circuits respectively connected with the column lines COL, and in response to a shift of the comparison signal, the buffer BUF may latch the counting signal output from the counter CNT for each column and may output the latched counting signal as data.

In some implementations, the ADC 35 may further include correlated double sampling (CDS) circuits which calculate a difference between a reference voltage representing a reset state of unit pixels and an output voltage representing a signal component corresponding to incident light to perform a CDS operation and outputs an analog sampling signal corresponding to a valid signal component. The CDS circuits may be connected with the column lines COL.

The timing controller 32 may control an operation timing of each of the row driver 31 and the ADC 35. The timing controller 32 may provide a timing signal and a control signal to the row driver 31 and the ADC 35. In more detail, the timing controller 32 may control the ADC 35, and the ADC 35 may provide data to the logic circuit 30, based on control by the timing controller 32. Also, the timing controller 32 may further include circuits which provide a request, a command, or an address to the logic circuit 30 so that data of the ADC 35 is stored in a memory cell array.

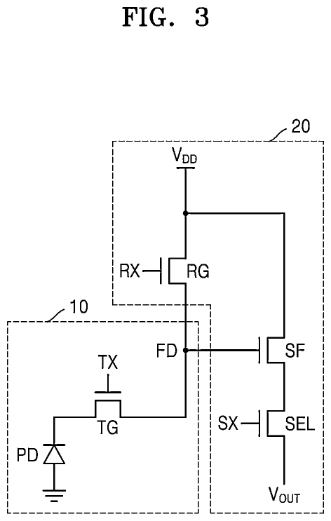

FIG. 3 is a circuit diagram of an example of a unit pixel of the first pixel array 10 and the second pixel array 20 of FIG. 1 according to some implementations. For example, FIG. 3 may be a 4 T structure of a unit pixel configuring the first pixel array 10 and the second pixel array 20.

In FIG. 3, the first pixel array 10 may include a photoelectric conversion layer PD, a transfer transistor TG, and a floating diffusion region FD. The second pixel array 20 may include a reset transistor RG, a source follower transistor SF, and a selection transistor SEL.

The photoelectric conversion layer PD may generate an electric charge in proportion to the amount of light incident from the outside. The photoelectric conversion layer PD may be coupled to the transfer transistor TG that transfers generated and accumulated electric charges to the floating diffusion region FD. The floating diffusion region FD may be a region that converts an electric charge into a voltage and may have a parasitic capacitance, and electric charges may be accumulated and stored in the floating diffusion region FD. An electric charge accumulated in the floating diffusion region FD may be converted into a voltage. For example, a ratio at which electric charges accumulated in the floating diffusion region FD are converted into a voltage may be referred to as a conversion gain. The conversion gain may vary based on a capacitance of the floating diffusion region FD. When a capacitance of the floating diffusion region FD increases, the conversion gain may decrease, and when a capacitance of the floating diffusion region FD decreases, the conversion gain may increase. According to some implementations, a connection structure between the transfer transistor TG and the floating diffusion region FD capable of increasing the conversion gain may be proposed.

One end of the transfer transistor TG may be connected with the photoelectric conversion layer PD, and the other end of the transfer transistor TG may be connected with the floating diffusion region FD. The transfer transistor TG may be provided as a transistor which is driven by a certain bias (for example, a transfer signal TX). For example, the transfer transistor TG may transfer an electric charge, generated from the photoelectric conversion layer PD, to the floating diffusion region FD according to the transfer signal TX. According to some implementations, the transfer transistor TG may have a structure of a vertical transfer gate (VTG) capable of increasing the transfer efficiency of a photocharge.

The source follower transistor SF may amplify a variation of an electric potential of the floating diffusion region FD receiving a photocharge from the photoelectric conversion layer PD and may output an amplified variation to an output line VOUT. When the source follower transistor SF is turned on, a certain electric potential (for example, a source voltage VDD) provided to a drain of the source follower transistor SF may be transferred to a drain region of the selection transistor SEL.

The selection transistor SEL may select a unit pixel which is to be read by row units. The selection transistor SEL may be provided as a transistor which is driven by a selection line for applying a certain bias (for example, a row selection signal SX).

The reset transistor RG may periodically reset the floating diffusion region FD. The reset transistor RG may be provided as a transistor which is driven by a reset line for applying a certain bias (for example, a reset signal RX). When the reset transistor RG is turned on by the reset signal RX, a certain electric potential (for example, the source voltage VDD) provided to a drain of the reset transistor RG may be transferred to the floating diffusion region FD.

According to some implementations, as an area of a unit pixel decreases, the photoelectric conversion layer PD and the transfer transistor TG may be formed in a first semiconductor chip (100 of FIG. 1), and the reset transistor RG, the source follower transistor SF, and the selection transistor SEL may be formed in a second semiconductor chip (200 of FIG. 1). The first semiconductor chip and the second semiconductor chip may be aligned to configure a unit pixel.

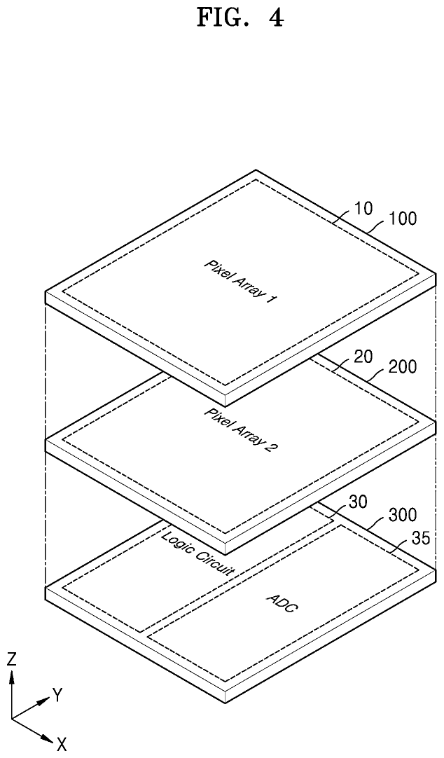

FIG. 4 is a perspective view of the first pixel array 10, the second pixel array 20, the logic circuit 30, and the ADC 35 of the image sensor of FIG. 1 according to some implementations. In FIG. 4, in an image sensor according to some implementations, first to third semiconductor chips 100 to 300 may be sequentially stacked. In FIG. 4, sizes of the first semiconductor chip 100, the second semiconductor chip 200, and the third semiconductor chip 300 are shown to be equal to one another, but the sizes are not limited thereto. In some implementations, sizes of the first semiconductor chip 100, the second semiconductor chip 200, and the third semiconductor chip 300 may differ. As described above, the first pixel array 10 may be disposed in the first semiconductor chip 100, and the second pixel array 20 may be disposed in the second semiconductor chip 200. A logic circuit 30 and an ADC 35 may be disposed in the third semiconductor chip 300.

In the first semiconductor chip 100, a plurality of unit pixels may be arranged in a two-dimensional (2D) array structure with respect to a 2D plane. In some implementations, the first pixel array 10 may include a sensor array region and a pad region. The sensor array region may be disposed at, for example, a center portion of the first semiconductor chip 100, and the pad region may be disposed at, for example, an edge of the first semiconductor chip 100, but the deposition of the sensor array region and the pad region are not limited thereto.

Active pixels that are supplied with light to generate an active signal may be arranged in the sensor array region. The second pixel array 20 may transfer a control signal to the sensor array region of the first pixel array 10. The second pixel array 20 may transfer an output signal of a unit pixel to the logic circuit 30 of the third semiconductor chip 300. The pad region may be configured to transfer and receive an electrical signal between the image sensor according to some embodiments and an external device.

The logic circuit 30 may include circuits for processing a pixel signal received from each unit pixel. The logic circuit 30 may receive an image signal from the ADC 35 and may process the image signal.

FIG. 5A is a cross-sectional view of an example of a first pixel array 10a of an image sensor according to some implementations. In FIG. 5A, a transfer transistor, a floating diffusion region, and a contact connection structure for connecting the elements with each other, which are included in the first pixel array 10a of the image sensor according to some implementations, are illustrated. The cross-sectional view of FIG. 5A may be a cross-sectional view corresponding to a partial region of a first semiconductor chip where the first pixel array 10a is provided.

In FIG. 5A, the first pixel array 10a may include a first substrate 110a, a first interlayer insulation layer 120a, and a second interlayer insulation layer 130a. The first substrate 110a, the first interlayer insulation layer 120a, and the second interlayer insulation layer 130a may be sequentially stacked and arranged in a Z-axis direction.

The first substrate 110a may include a semiconductor material, such as Group IV semiconductor materials, Group III-V semiconductor materials, or Group II-VI semiconductor materials. The Group IV semiconductor materials may include, for example, silicon (Si), germanium (Ge), or silicon germanium (SiGe). The Group III-V semiconductor materials may include, for example, gallium arsenide (GaAs), indium phosphide (InP), gallium phosphide (GaP), indium arsenide (InAs), indium antimony (InSb), or indium gallium arsenic (InGaAs). The Group II-VI semiconductor materials may include, for example, tellurium zinc (TeZn) or sulfur cadmium (CdS).

In some implementations, color filters and micro-lenses may be formed under the first substrate 110a. A structure, where the color filters and the micro-lenses are formed in a direction opposite to the first interlayer insulation layer 120a with respect to the first substrate 110a where pixels are formed, may be referred to as a backside illumination (BSI) structure. In some implementations, a structure, where the color filters and the micro-lenses are formed in the same direction as the first interlayer insulation layer 120a with respect to the first substrate 110a (i.e., a structure where the color filters and the micro-lenses are formed on the first interlayer insulation layer 120a), may be referred to as a front-side illumination (FSI) structure. Although an image sensor having the BSI structure may be described, an image sensor is not limited thereto.

The first interlayer insulation layer 120a may cover a vertical transfer gate 11a_1 of the first substrate 110a. The first interlayer insulation layer 120a may include a multi-layer structure. The first interlayer insulation layer 120a may include, for example, silicon oxide, silicon nitride, or a combination thereof. In some implementations, the first interlayer insulation layer 120a may include a low-k dielectric material having a dielectric constant that is less than a dielectric constant of silicon oxide.

The second interlayer insulation layer 130a may be disposed on the first interlayer insulation layer 120a. The second interlayer insulation layer 130a may include, for example, silicon oxide, silicon nitride, or a combination thereof. According to some implementations, a material of the first interlayer insulation layer 120a may differ from a material of the second interlayer insulation layer 130a.

A plurality of floating diffusion regions 12a_1 and 12a_2 may be included in the first substrate 110a. The plurality of floating diffusion regions 12a_1 and 12a_2 may be disposed in the first substrate 110a to be adjacent to a first surface 120a_2 of the first substrate 110a. Each of the plurality of floating diffusion regions 12a_1 and 12a_2 may be an impurity region of the first substrate 110a.

The first substrate 110a may further include a plurality of vertical transfer gates (for example, first and second vertical transfer gates) 11a_1 and 11a_2. In some implementations, the vertical transfer gates 11a_1 and 11a_2 may be recessed into the first substrate 110a from the first surface 120a_2 of the first substrate 110a. In some implementations, unlike that shown in FIG. 5A, the vertical transfer gates 11a_1 and 11a_2 may not be recessed into the first substrate 110a. According to some implementations, the vertical transfer gates 11a_1 and 11a_2 may be included in the transfer transistor TG of FIG. 3. Source/drain regions 11a_d and 11a_s may be disposed at both sides of the vertical transfer gates 11a_1 and 11a_2. The first substrate 110a may include shallow trench isolation (STI) regions 150a_1 to 150a_3. The STI regions 150a_1 to 150a_3 may include an insulating material. The STI regions 150a_1 to 150a_3 may include, for example, oxide, nitride, or a combination thereof. The arrangement of lower surfaces of the STI regions 150a_1 to 150a_3 is not limited to that shown in FIG. 5A, but may be variously modified according to some implementations. An oxide layer 140a may be disposed between the first substrate 110a and the first interlayer insulation layer 120a. In FIG. 5A, the vertical transfer gates 11a_1 and 11a_2 may be provided as two, and the floating diffusion regions 12a_1 and 12a_2 may be provided as two. The vertical transfer gate and the floating diffusion region may be a vertical transfer gate and a floating diffusion region respectively included in different unit pixels, or may be a vertical transfer gate and a floating diffusion region included in one unit pixel.

The first interlayer insulation layer 120a may include a first contact 13a_1 that is electrically connected with the first vertical transfer gate 11a_1 and extends in the Z-axis direction and a second contact 13a_2 that is electrically connected with the second vertical transfer gate 11a_2 and extends in the Z-axis direction. The first interlayer insulation layer 120a may include a plurality of third contacts 13a_3 and 13a_4 that are respectively and electrically connected with the floating diffusion regions 12a_1 and 12a_2 and extend in the Z-axis direction and a first metal region 14a that electrically connects the plurality of third contacts 13a_3 and 13a_4 with each other and extends in an X-axis direction.

In FIG. 5A, the plurality of floating diffusion regions 12a_1 and 12a_2 may be electrically connected with each other by the first metal region 14a that extends in the X-axis direction. The first metal region 14a may be disposed so that one side surface thereof contacts the first surface 120a_1 of the first interlayer insulation layer 120a. The first metal region 14a, the first contact 13a_1, and the second contact 13a_2 may each extend in the Z-axis direction to contact the first surface 120a_1 of the first interlayer insulation layer 120a.

In FIG. 5A, a structure where the plurality of third contacts 13a_3 and 13a_4 and the first metal region 14a are connected with each other and provided as one may be provided. The plurality of third contacts 13a_3 and 13a_4 may respectively extend in the Z-axis direction in the floating diffusion regions 12a_1 and 12a_2 and may be regions that do not contact the first interlayer insulation layer 120a. The first metal region 14a may be a region that is disposed between an upper surface of each of the plurality of third contacts 13a_3 and 13a_4 and the first surface 120a_1 of the first interlayer insulation layer 120a.

According to some implementations, the first contact 13a_1, the second contact 13a_2, the plurality of third contacts 13a_3 and 13a_4, and the first metal region 14a may include a metal material. According to some implementations, the first contact 13a_1, the second contact 13a_2, the plurality of third contacts 13a_3 and 13a_4, and the first metal region 14a may include a conductive material. According to some implementations, the first contact 13a_1, the second contact 13a_2, the plurality of third contacts 13a_3 and 13a_4, and the first metal region 14a all be formed of the same material. Relationships between the first contact 13a_1, the second contact 13a_2, the plurality of third contacts 13a_3 and 13a_4, and the first metal region 14a are described in detail with reference to FIG. 5B.

The second interlayer insulation layer 130a may include a plurality of first vias 15a_1 and 15a_3, a second via 15a_2, a plurality of second metal regions 16a_1 and 16a_3, and a third metal region 16a_2. The first via 15a_1 may electrically connect the second metal region 16a_1 with the first contact 13a_1. The second via 15a_2 may electrically connect the third metal region 16a_2 with the first metal region 14a. The first via 15a_3 may electrically connect the second metal region 16a_3 with the second contact 13a_2. According to some implementations, the plurality of first vias 15a_1 and 15a_3, the second via 15a_2, the plurality of second metal regions 16a_1 and 16a_3, and the third metal region 16a_2 may include materials which differ from those of the first contact 13a_1, the second contact 13a_2, the plurality of third contacts 13a_3 and 13a_4, and the first metal region 14a. According to some implementations, the first contact 13a_1, the second contact 13a_2, the plurality of third contacts 13a_3 and 13a_4, and the first metal region 14a may include tungsten (W), and the plurality of first vias 15a_1 and 15a_3, the second via 15a_2, the plurality of second metal regions 16a_1 and 16a_3, and the third metal region 16a_2 may include copper (Cu). According to some implementations, the second metal regions 16a_1 and 16a_3 and the third metal region 16a_2 may be metal layers that are disposed on the same layer.

FIG. 5B is a diagram of an example of relationships between contacts included in the first pixel array 10a of FIG. 5A according to some implementations. In FIG. 5B, relationships are shown between a plurality of third contacts 13a_3 and 13a_4 and a first metal region 14a, connected with the plurality of floating diffusion regions 12a_1 and 12a_2 illustrated in FIG. 5A, and a first contact 13a_1 and a second contact 13a_2 that are respectively connected with the vertical transfer gates 11a_1 and 11a_2. For example, a thickness may denote a width of a corresponding clement in a Z-axis direction, and a height may denote a numerical value corresponding to a highest position at which the corresponding element is disposed in the Z-axis direction.

According to some implementations, a thickness of a first interlayer insulation layer 120a where the first contact 13a_1, the second contact 13a_2, the plurality of third contacts 13a_3 and 13a_4, and the first metal region 14a are formed may be d4. A thickness of the first metal region 14a may be d2. A thickness of the first contact 13a_1 may be d1. A thickness of the second contact 13a_2 may be d1. A thickness of the third contacts 13a_3 and 13a_4 may be d3. According to some implementations, a sum of the thickness of the third contacts 13a_3 and 13a_4 and the thickness of the first metal region 14a may be the same as the thickness of the first interlayer insulation layer 120a.

In FIG. 5B, a height of each of vertical transfer gates 11a_1 and 11a_2 may be h1, and a height of each of the third contacts 13a_3 and 13a_4 may be h2. According to some implementations, a height of the first metal region 14a may be h3. According to some implementations, a height of each of the first contact 13a_1 and the second contact 13a_2 may be h3.

According to some implementations, thicknesses of the first contact 13a_1, the second contact 13a_2, and the plurality of third contacts 13a_3 and 13a_4 may be equal to one another, or may differ. In some implementations, the height of the first metal region 14a may have the same value as the height of each of the first contact 13a_1 and the second contact 13a_2. According to some implementations, one side surface of the first metal region 14a may contact an upper surface of each of the plurality of third contacts 13a_3 and 13a_4, and the other side surface of the first metal region 14a may contact a first surface of the first interlayer insulation layer 120a.

In FIG. 5B, a distance between the plurality of floating diffusion regions 12a_1 and 12a_2 may be P1. According to some implementations, P2, which is a length of the first metal region 14a in an X-axis direction, may have a value that is greater than the distance between the plurality of floating diffusion regions 12a_1 and 12a_2.

In some implementations, a height of the first metal region 14a connecting the plurality of third contacts 13a_3 and 13a_4 with each other in the X-axis direction and a height of each of the first contact 13a_1 and the second contact 13a_2 respectively connected with the vertical transfer gates 11a_1 and 11a_2 may be set to be equal to each other, and a connection with a source follower transistor formed in a second semiconductor chip may be easily performed. Also, as the first metal region 14a is provided, a distance between the floating diffusion regions 12a_1 and 12a_2 and a metal layer connected with the source follower transistor may increase, and thus, a capacitance may decrease, thereby securing a conversion gain.

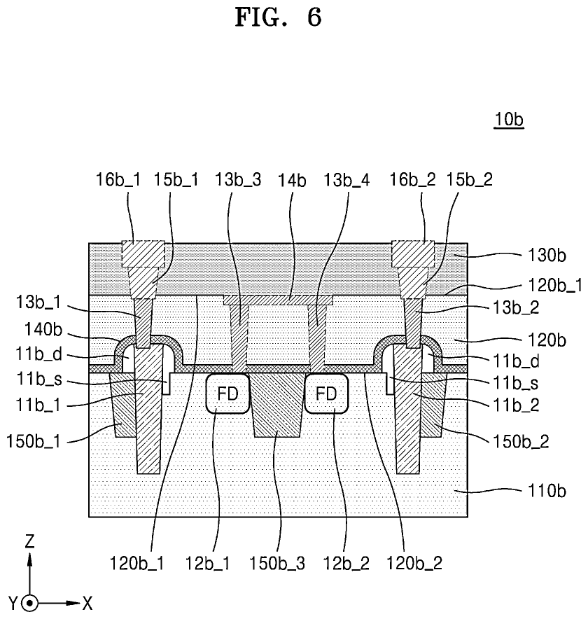

FIG. 6 is a cross-sectional view of an example of a first pixel array 10b of an image sensor according to some implementations. For convenience, descriptions with respect to FIG. 6 that are the same as or similar to the descriptions of FIG. 5 are omitted.

In FIG. 6, the first pixel array 10b may be formed in a first semiconductor chip and may include a first substrate 110b, a first interlayer insulation layer 120b, and a second interlayer insulation layer 130b. The first substrate 110b may include a plurality of floating diffusion regions 12b_1 and 12b_2, vertical transfer gates 11b_1 and 11b_2, source/drain regions 11b_s and 11b_d, and STI regions 150b_1 to 150b_3.

The first interlayer insulation layer 120b may include a first contact 13b_1, a second contact 13b_2, a plurality of third contacts 13b_3 and 13b_4, and a first metal region 14b. The second interlayer insulation layer 130b may include first vias 15b_1 and 15b_2 and second metal regions 16b_1 and 16b_2. The second interlayer insulation layer 130b may include a first via 15b_1 connecting the first contact 13b_1 with the second metal region 16b_1 and a first via 15b_2 connecting the second contact 13b_2 with the second metal region 16b_2. Compared to the first pixel array 10a of FIG. 5A, the second interlayer insulation layer 130b included in the first pixel array 10b of FIG. 6 may not include a second via which connects the first metal region 14b with a third metal region.

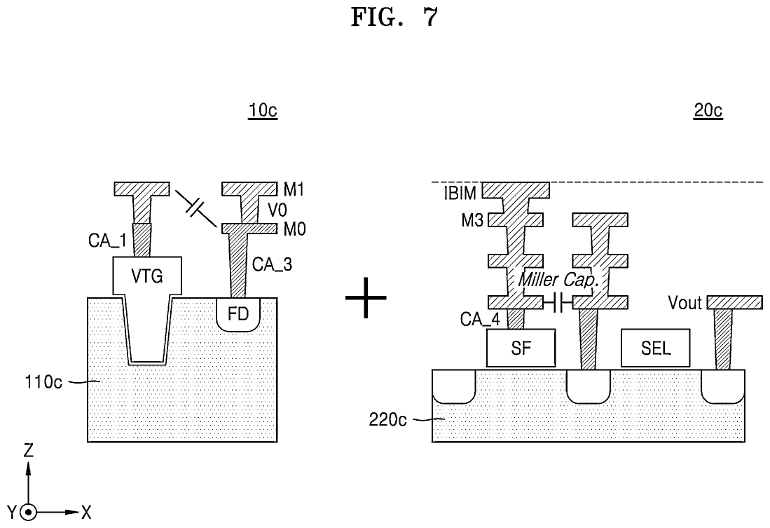

FIG. 7 is a diagram of an example of a connection relationship between elements included in a first pixel array 10c and a second pixel array 20c of an image sensor according to some implementations. In FIG. 7, a cross-sectional view corresponding to the first pixel array 10c of the image sensor according to some implementations and a cross-sectional view corresponding to the second pixel array 20c are illustrated.

In FIG. 7, the first pixel array 10c includes a floating diffusion region FD and a vertical transfer gate VTG each formed in a first substrate 110c. In the first pixel array 10c, a third contact CA_3 extending in a Z-axis direction in a floating diffusion region FD and a first metal region M0 extending in an X-axis direction may be provided, and a first contact CA_1 extending in the Z-axis direction up to a height corresponding to the first metal region M0 from a vertical transfer gate VTG may be provided. A height of the first contact CA_1 connected with the vertical transfer gate VTG may be equal to that of each of the first metal region M0 and the third contact CA_3 connected with the floating diffusion region FD. A first via V0 and a second metal region M1 may be respectively connected with the first contact CA_1 and the first metal region M0 each having the same height.

In FIG. 7, a conversion gain of a stacked image sensor may be improved by using the first metal region M0 included in the first pixel array 10c. According to some implementations, floating diffusion regions may be electrically connected with each other through the third contact CA_3 and the first metal region M0 which are formed by the same process. The same process may be a dual damascene process. According to some implementations, in order to decrease a capacitance of a floating diffusion region in an upper substrate, a distance between the floating diffusion region FD and the second metal region M1 may increase by adding the first metal region M0. According to some implementations, a plurality of floating diffusion regions may be electrically connected with one another through the first metal region M0, and a source follower transistor of a second semiconductor chip may be connected with the plurality of floating diffusion regions through the first metal region M0, the first via V0, and the second metal region M1. For example, a step height may be formed through the first metal region M0. According to some implementations, a connection with a subsequent layer may be easily performed through the first contact CA_1 and the first metal region M0 each having the same height.

In FIG. 7, in the second pixel array 20c, source/drain regions respectively corresponding to a source follower transistor SF and a selection transistor SEL may be included in a second substrate 220c. A gate of the source follower transistor SF and a gate of the selection transistor SEL may be disposed on the second substrate 220c. The gate of the source follower transistor SF may include a plurality of metal regions M3 and contacts CA_4 which are formed to extend in the Z-axis direction.

According to some implementations, in the first pixel array 10c, the first metal region M0 may have the same height as that of the first contact CA_1 and may be formed by a dual damascene process, and a process may be simplified. Also, a step height with the second metal region M2 may be formed through the first via V0, and a connection with the source follower transistor SF of the second pixel array 20c may be easily performed through the first via V0 and the second metal region M1. In the first pixel array 10c and the second pixel array 20c, the first pixel array 10c may be connected with the second pixel array 20c by using a C2C scheme, a deep contact scheme, or a scheme of connecting a plurality of metal layers with one another.

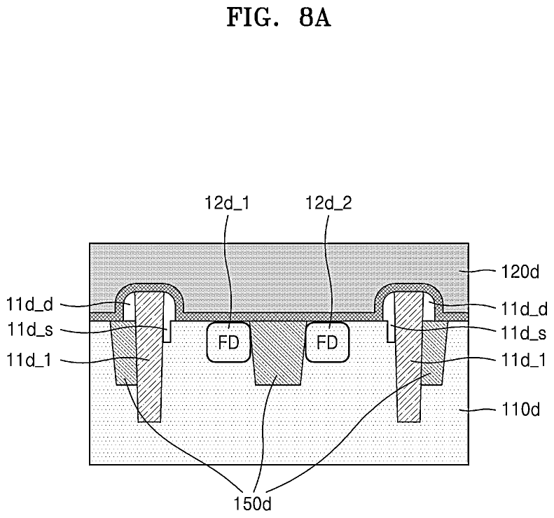

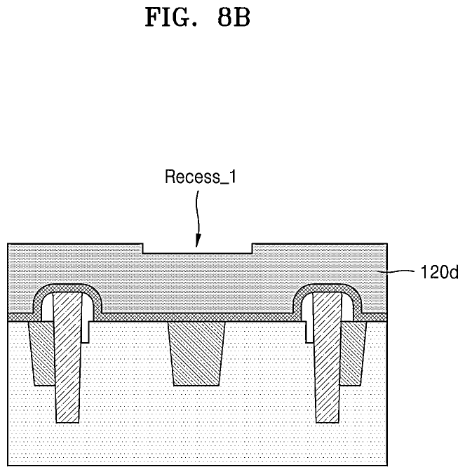

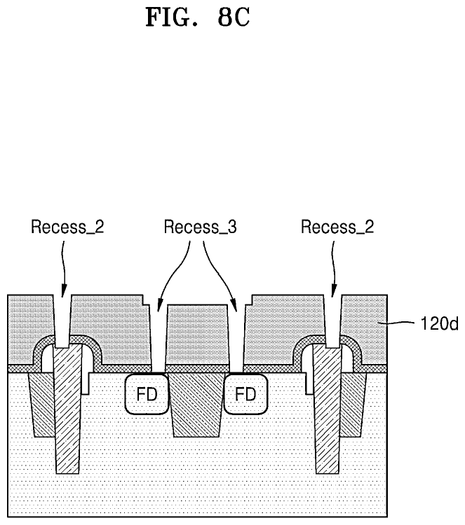

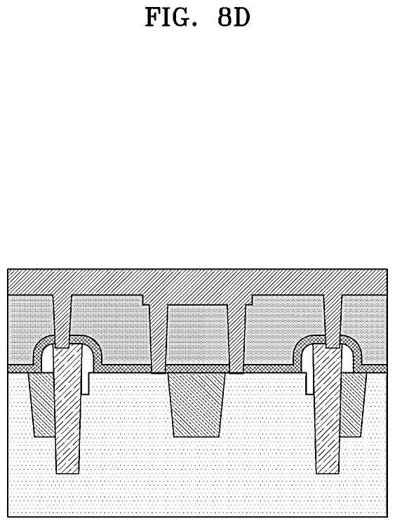

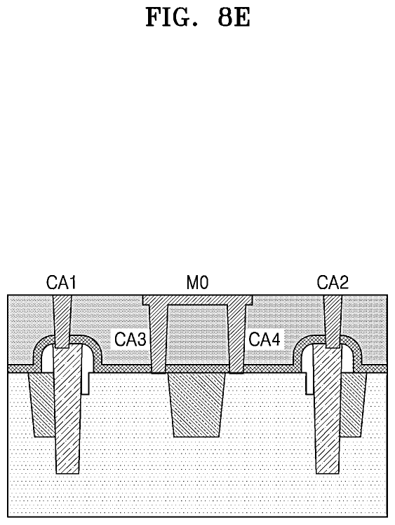

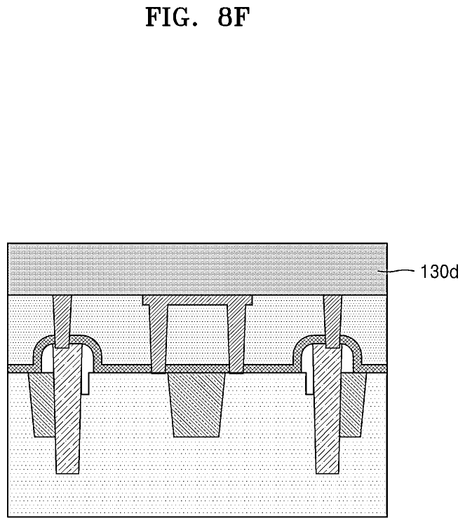

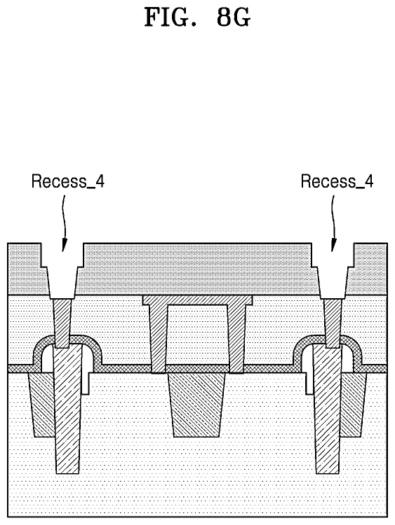

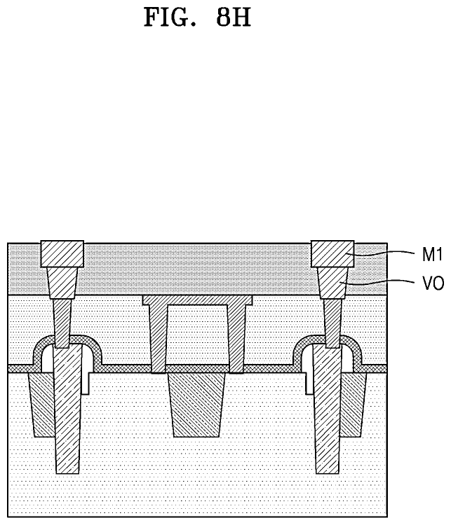

FIGS. 8A to 8H are cross-sectional views of an example of a method of manufacturing an image sensor according to some implementations. In FIG. 8A, elements corresponding to a transfer transistor may be formed in a first substrate 110d. Vertical transfer gates 11d_1 and 11d_2, source/drain regions 11d_s and 11d_d, a floating diffusion region FD, and an STI region 150d may be formed in the first substrate 110d. An oxide layer 140d covering the vertical transfer gates 11d_1 and 11d_2 may be formed, and a first interlayer insulation layer 120d may be formed thereon. In some implementations, this may be formed by a deposition process.

In FIG. 8B, a first recess region Recess_1 may be formed by a mask pattern for forming a first metal region. According to some implementations, an anisotropic etching process may be performed on the first interlayer insulation layer 120d for forming the first metal region, and thus, the first recess region Recess_1 may be formed. The first recess region Recess_1 may be formed by a wet etching processor or a dry etching process. According to some implementations, a thickness of the first recess region Recess_1 may be formed to be maximally thin.

In FIG. 8C, a second recess region Recess_2 may be formed by performing an anisotropic etching process on the first interlayer insulation layer 120d so as to form a first contact and a second contact, and a third recess region Recess_3 may be formed by performing an anisotropic etching process on the first interlayer insulation layer 120d so as to form a plurality of third contacts. The second recess region Recess_2 and the third recess region Recess_3 may be formed by a wet etching processor or a dry etching process. The second recess region Recess_2 may be connected with the vertical transfer gates 11d_1 and 11d_2, and the third recess region Recess_3 may be connected with a floating diffusion region FD. According to some implementations, the order of an operation of FIG. 8B and an operation of FIG. 8C may be changed.

In FIG. 8D, the first recess region Recess_1, the second recess region Recess_2, and the third recess region Recess_3 may be simultaneously deposited. This may be a dual damascene process. Accordingly, the first contact CA_1, the second contact CA_2, the plurality of third contacts CA_3, and the first metal region M0 may be simultaneously formed. According to some implementations, a deposited material may be tungsten (W).

In FIG. 8E, a chemical mechanical polishing (CMP) process may be performed with a height corresponding to the first metal region. Based thereon, the first contact CA_1, the second contact CA_2, the plurality of third contacts CA_3, and the first metal region M0 may have the same height.

In FIG. 8F, a second interlayer insulation layer 130d may be formed. For example, a material that is deposited for forming the second interlayer insulation layer 130d may be a material that differs from a material deposited for forming the first interlayer insulation layer 120d.

In FIG. 8G, a fourth recess region Recess_4 may be formed in the second interlayer insulation layer 130d. According to some implementations, an anisotropic etching process may be performed on the second interlayer insulation layer 130d for forming the second metal region and the first via, and the fourth recess region Recess_4 may be formed. The fourth recess region Recess_4 may be connected with the first contact CA_1 and the second contact CA_2.

In FIG. 8H, a deposition process for filling the fourth recess region Recess_4 may be performed. This may be a dual damascene process. Accordingly, the first via V0 and the second metal region M1 may be simultaneously formed. According to some implementations, a deposited material may be copper (Cu). According to some implementations, a material that is deposited in the dual damascene process in an operation of FIG. 8D may differ from a material that is deposited in the dual damascene process in an operation of FIG. 8H.

In view of FIGS. 8A-8H, a first pixel array corresponding to FIG. 6 may be formed. A first pixel array corresponding to FIG. 5A may be formed by extending a range of the fourth recess region Recess_4 of FIG. 8H.

In the method of manufacturing the image sensor of FIGS. 8A to 8H, an example of a method of manufacturing a region corresponding to the first pixel array of the image sensor has been described. According to some implementations, in a process of an image sensor that is implemented by stacking three chips, a distance between a floating diffusion region and a second metal region may increase for reducing a capacitance of the floating diffusion region. Accordingly, in some implementations, a connection between a plurality of floating diffusion regions may be performed by using a first metal region, a height of the first metal region may be equal to that of a first contact connected with a vertical transfer gate, and a connection with a source follower transistor in a different chip may be easily performed by connecting a first via with a second metal region.

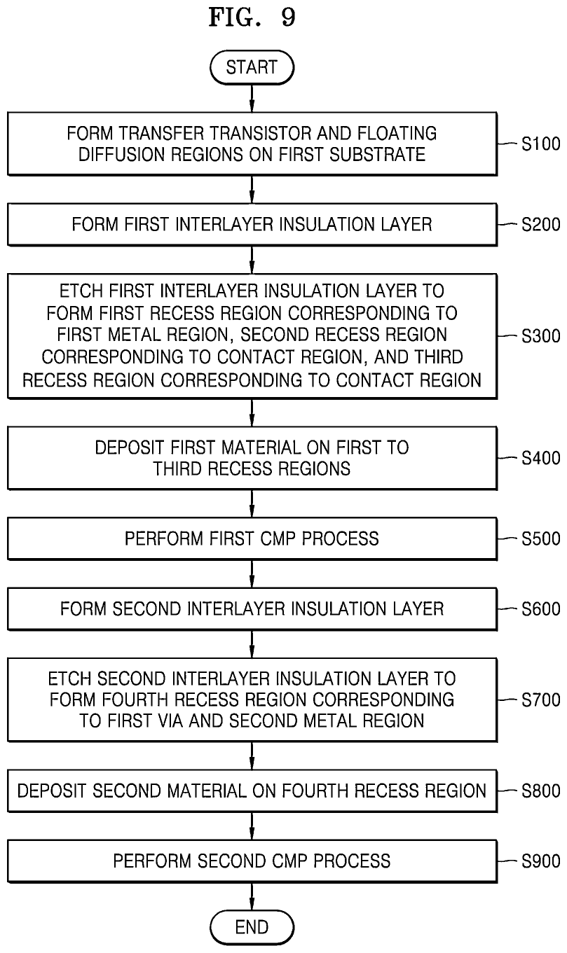

FIG. 9 is a flowchart of an example of a method of manufacturing an image sensor according to some implementations. In FIG. 9, referring to operation S100, a transfer transistor and a floating diffusion region may be formed in a first substrate. This may be an operation corresponding to FIG. 8A.

Referring to operation S200, a first interlayer insulation layer may be formed. The first interlayer insulation layer may be formed on the first substrate. This may be an operation corresponding to FIG. 8A.

Referring to operation S300, a first recess region corresponding to a first metal region and second and third recess regions corresponding to a contact region may be formed by etching the first interlayer insulation layer. This may be an operation corresponding to FIGS. 8B and 8C. The second recess region may be a recess region for forming a contact connected with a vertical transfer gate, and the third recess region may be a recess region for forming a contact connected with a floating diffusion region. According to some implementations, the first recess region may have a length that is longer than a distance between a plurality of floating diffusion regions.

Referring to operation S400, a deposition process using a first material may be performed on the first recess region and the third recess region. This may be an operation corresponding to FIG. 8D.

Referring to operation S500, a first CMP process may be performed. This may be an operation corresponding to FIG. 8E. Based on operation S400 and operation S500, a first contact, a second contact, and a plurality of third contacts each having the same height and a first metal region connected with the first to third contacts may be formed by a dual damascene process, and by simultaneously forming the first to third contacts and the first metal region, an effect of simplifying a process may be obtained.

Referring to operation S600, a second interlayer insulation layer may be formed by depositing. This may be an operation corresponding to FIG. 8F. According to some implementations, a material included in the first interlayer insulation layer may not completely be equal to a material included in the second interlayer insulation layer.

Referring to operation S700, a fourth recess region corresponding to a first via and a second metal region may be formed by etching the second interlayer insulation layer. This may be an operation corresponding to FIG. 8G.

Referring to operation S800, a second material may be deposited on the fourth recess region.

Referring to operation S900, a second CMP process may be performed. Operations S800 and S900 may each be an operation corresponding to FIG. 8H.

Based on operations S700 to S900, the first via and second metal regions may be simultaneously formed, and an effect of simplifying a process may be obtained. Also, the first via and the second metal regions may be formed by a dual damascene process. Conductive materials included in the first via and the second metal regions may differ from conductive materials included in the first contact, the second contact, the plurality of third contacts, and the first metal region.

According to some implementations, in connecting a floating diffusion region disposed in a first semiconductor chip with a source follower transistor disposed in a second semiconductor chip, a connection structure for increasing a conversion gain may be proposed. To increase the conversion gain, it may be required to reduce a capacitance of the floating diffusion region. According to some implementations, in order to increase a distance between the floating diffusion region and metal layers for connection with the other element, a first metal region for a connection between floating diffusion regions may be added, and based on a first via and a second metal region capable of being connected with the first metal region, a connection with the source follower transistor may be performed.

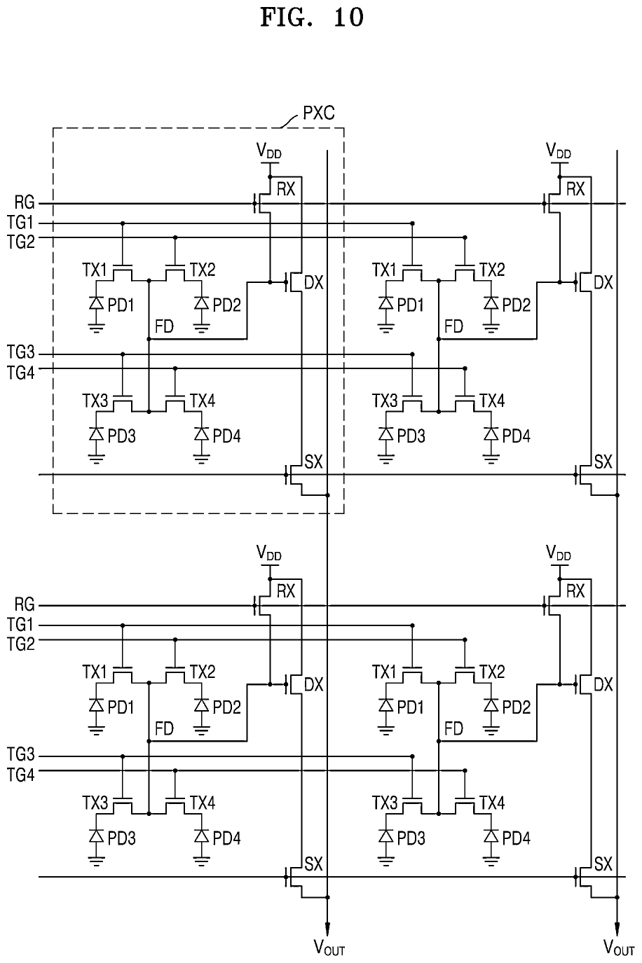

FIG. 10 is a diagram of an example of a pixel circuit of an image sensor according to some implementations. In FIG. 10, each of a plurality of unit pixels PX included in an image sensor according to some implementations may include a pixel circuit PXC corresponding thereto. The pixel circuit PXC may include a plurality of photodiodes PD1 to PD4 included in each of the plurality of unit pixels PX and a plurality of semiconductor devices for processing electric charges generated in the plurality of photodiodes PD1 to PD4. For example, the pixel circuit PXC may include a first photodiode PD1, a second photodiode PD2, a third photodiode PD3, and a fourth photodiode PD4. The pixel circuit PXC may include first to fourth transfer transistors TX1 to TX4 respectively corresponding to the plurality of photodiodes PD1 to PD4, a reset transistor RX, a selection transistor SX, and a driving transistor DX. The photodiodes PD1 to PD4 included in the pixel circuit PXC may share the floating diffusion region FD, the reset transistor RX, the selection transistor SX, and the driving transistor DX.

Additionally, gate electrodes of a plurality of transistors TX1 to TX4, RX, SX, and DX included in the pixel circuit PXC may be respectively connected with driving signal lines. For example, the first to fourth transfer transistors TX1 to TX4 may receive transfer control signals TG1 to TG4 through transfer control signal lines to operate, the reset transistor RX may receive a reset control signal RG through a reset control signal line to operate, and the selection transistor SX may receive a selection control signal SG to operate. However, this configuration is not limited to the illustration of FIG. 10, and the pixel circuit PXC may be designed as various types. For example, the pixel circuit PXC may include semiconductor devices for processing an electric charge generated in a photodiode by units which are greater or less than the unit pixel PX.

The first to fourth transfer transistors TX1 to TX4 may be respectively connected with the first to fourth photodiodes PD1 to PD4. Also, the first to fourth transfer transistors TX1 to TX4 may share the floating diffusion region FD. The first to fourth photodiodes PD1 to PD4 may generate electric charges in proportion to the amount of light incident from the outside and may accumulate the generated electric charges therein, respectively.

The first to fourth transfer transistors TX1 to TX4 may sequentially transfer the electric charges, accumulated in the first to fourth photodiodes PD1 to PD4, to the floating diffusion region FD. To transfer an electric charge, generated by one of the first to fourth photodiodes PD1 to PD4, to the floating diffusion region FD, different transfer control signals TG1 to TG4 may be applied to gate electrodes of the first to fourth transfer transistors TX1 to TX4. Accordingly, the floating diffusion region FD may accumulate an electric charge generated by at least one of the first to fourth photodiodes PD1 to PD4.

According to some implementations, electric charges based on four photodiodes may be accumulated in the floating diffusion region FD. The floating diffusion region FD connected with four photodiodes may be provided as a plurality of floating diffusion regions (for example, four floating diffusion regions) respectively corresponding to four transfer transistors, and the plurality of floating diffusion regions may be electrically connected with one another through a first metal region. In FIG. 10, four floating diffusion regions may be electrically connected with one another through the first metal region, and according to another embodiment, eight floating diffusion regions may be electrically connected with one another through the first metal region. Accordingly, gates of a plurality of transfer transistors may be connected with a first via through a separate contact.

The reset transistor RX may periodically reset an electric charge accumulated in the floating diffusion region FD. For example, electrodes of the reset transistor RX may be connected to the floating diffusion region FD and a source voltage VDD. When the reset transistor RX is turned on, an electric charge accumulated in the floating diffusion region FD by an electric potential difference with the source voltage VDD may be discharged, and the floating diffusion region FD may be reset and a voltage of the floating diffusion region FD may be equal to the source voltage VDD.

An operation of the driving transistor DX may be controlled based on the amount of electric charge accumulated in the floating diffusion region FD. The driving transistor DX may be combined with a current source disposed outside the unit pixel PX to function as a source follower buffer amplifier. For example, as an electric charge is accumulated in the floating diffusion region FD, an electric potential variation may be amplified and may be output to an output line Vout.

The selection transistor SX may select unit pixels which are to be read by row units. When the selection transistor SX is turned on, an electrical signal output from the driving transistor DX may be transferred to the selection transistor SX.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to embodiments thereof, it will be understood that various changes in form and details may be made therein without departing from the spirit and scope of the following claims.

1. A stacked image sensor comprising:
a first semiconductor chip including:
a first photoelectric conversion layer, a first floating diffusion region, and a first transfer transistor electrically connecting the first photoelectric conversion layer to the first floating diffusion region; and
a second photoelectric conversion layer, a second floating diffusion region, and a second transfer transistor electrically connecting the second photoelectric conversion layer to the second floating diffusion region; and
a second semiconductor chip configured to output a pixel signal based on the first photoelectric conversion layer and the second photoelectric conversion layer,
wherein the second semiconductor chip includes at least one transistor,
wherein the first semiconductor chip comprises:
a first contact electrically connected to the first transfer transistor and extending in a Z-axis direction;
a second contact electrically connected to the second transfer transistor and extending in the Z-axis direction;
a plurality of third contacts electrically connected to each of the first floating diffusion region and the second floating diffusion region, the plurality of third contacts extending in the Z-axis direction; and
a first metal region configured to electrically connect the plurality of third contacts to one another and extending in an X-axis direction, and
wherein the first contact, the second contact, and the first metal region contact a first surface of a first interlayer insulation layer that defines the first contact, the second contact, and the first metal region.

2. The stacked image sensor of claim 1, wherein the first contact, the second contact, the first metal region, and the plurality of third contacts comprise a same conductive material.

3. The stacked image sensor of claim 2, wherein the first contact, the second contact, the first metal region, and the plurality of third contacts comprise tungsten.

4. The stacked image sensor of claim 1,
wherein the first semiconductor chip further comprises a second interlayer insulation layer disposed on the first surface of the first interlayer insulation layer, and
wherein the second interlayer insulation layer comprises:
a first via and a second metal region respectively connected to the first contact and the second contact; and
a second via and a third metal region each connected to the first metal region.

5. The stacked image sensor of claim 4, wherein the second metal region and the third metal region are metal layers of a same layer.

6. The stacked image sensor of claim 4, wherein the first via, the second metal region, the second via, and the third metal region comprise conductive materials different from conductive materials of the first contact, the second contact, the first metal region, and the plurality of third contacts.

7. The stacked image sensor of claim 1, wherein the second semiconductor chip further comprises a source follower transistor connected to the first floating diffusion region and the second floating diffusion region.

8. A stacked image sensor comprising:
a first semiconductor chip including:
a first photoelectric conversion layer, a first floating diffusion region, and a first transfer transistor electrically connecting the first photoelectric conversion layer to the first floating diffusion region; and
a second photoelectric conversion layer, a second floating diffusion region, and a second transfer transistor electrically connecting the second photoelectric conversion layer to the second floating diffusion region;
a second semiconductor chip configured to output a pixel signal based on the first photoelectric conversion layer and the second photoelectric conversion layer, the second semiconductor chip including at least one transistor; and
a third semiconductor chip including a circuit configured to process the pixel signal,
wherein the first semiconductor chip comprises:
a first contact electrically connected to the first transfer transistor and extending in a Z-axis direction;
a second contact electrically connected to the second transfer transistor and extending in the Z-axis direction;
a plurality of third contacts electrically connected with each of the first floating diffusion region and the second floating diffusion region and extending in the Z-axis direction; and
a first metal region configured to electrically connect the plurality of third contacts to one another and extending in an X-axis direction, and
wherein the first contact, the second contact, and the first metal region contact a first surface of a first interlayer insulation layer that defines the first contact, the second contact, and the first metal region.

9. The stacked image sensor of claim 8, wherein the first contact, the second contact, the first metal region, and the plurality of third contacts comprise a same conductive material.

10. The stacked image sensor of claim 8,
wherein the first semiconductor chip comprises a second interlayer insulation layer disposed on the first surface of the first interlayer insulation layer, and
wherein the second interlayer insulation layer comprises:
a first via and a second metal region respectively connected to the first contact and the second contact; and
a second via and a third metal region each connected to the first metal region.

11. The stacked image sensor of claim 10, wherein the first via, the second metal region, the second via, and the third metal region comprise conductive materials different from conductive materials of the first contact, the second contact, the first metal region, and the plurality of third contacts.

12. The stacked image sensor of claim 8,
wherein the second semiconductor chip further comprises a source follower transistor connected to the first floating diffusion region and the second floating diffusion region, and
wherein the third semiconductor chip comprises a plurality of logic circuits configured to control the source follower transistor.

13. The stacked image sensor of claim 12,
wherein the second semiconductor chip is disposed on the third semiconductor chip, and
wherein the first semiconductor chip is disposed on the second semiconductor chip.

14. The stacked image sensor of claim 8, wherein the first contact, the second contact, the first metal region, and the plurality of third contacts comprise tungsten.

15. The stacked image sensor of claim 11, wherein the first contact, the second contact, the first metal region, and the plurality of third contacts comprise tungsten, wherein the first via, the second metal region, the second via, and the third metal region comprise copper.

16. A stacked image sensor comprising:
a pixel array including a plurality of pixels;
a row driver configured to provide a control signal to the pixel array; and
a readout circuit configured to read a pixel signal output from a row line of the plurality of pixels selected by the row driver,
wherein each of the plurality of pixels comprises:
a first photodiode;
a first transfer transistor connected to the first photodiode;
a second photodiode;
a second transfer transistor connected to the second photodiode;
a plurality of floating diffusion regions configured to accumulate electric charges generated in the first photodiode and the second photodiode; and
a source follower transistor including a gate connected to the plurality of floating diffusion regions, and
wherein a first contact and a second contact are electrically connected to the first transfer transistor and the second transfer transistor, respectively, and extend in a Z-axis direction,
wherein a height of the first contact and a height of the second contact are equal to a height of a first metal region that electrically connects a plurality of third contacts electrically to one another, the plurality of third contacts being connected to each of the plurality of floating diffusion regions and extending in the Z-axis direction, and
wherein the first metal region extends in an X-axis direction.

17. The stacked image sensor of claim 16, wherein the first contact, the second contact, the plurality of third contacts, and the first metal region comprise a same conductive material.

18. The stacked image sensor of claim 17, wherein the first contact, the second contact, the plurality of third contacts, and the first metal region comprise tungsten.

19. The stacked image sensor of claim 16, wherein a height of each of the plurality of third contacts is equal to a difference between a height of the first metal region and a thickness of the first metal region.

20. The stacked image sensor of claim 16, wherein the first metal region is defined on the plurality of third contacts.

21.-24. (canceled)
